(19) United States
(12) Patent Application Publication
(10) Pub. No.: US 2026/0026323 A1
(43) Pub. Date: Jan. 22, 2026

(54) MOLYBDENUM NUCLEATION LAYER FORMATION

(71) Applicant: Applied Materials, Inc., Santa Clara, CA (US)

(72) Inventors: Jiajie CEN, Santa Clara, CA (US); Yu-Heng DENG, Santa Clara, CA (US); Junyeong YUN, Santa Clara, CA (US); Shiyu YUE, Santa Clara, CA (US); Ya-Hsi HWANG, Santa Clara, CA (US); Sahil Jaykumar PATEL, Sunnyvale, CA (US)

(21) Appl. No.: 18/777,542

(22) Filed: Jul. 19, 2024

(51) Int. Cl. H01L 21/768; H01L 21/3205

(52) U.S. Cl. CPC H01L 21/76876; H01L 21/32051; H01L 21/76879; H01L 21/76807

(57) ABSTRACT

Embodiments of the disclosure include apparatus and methods for molybdenum nucleation layer formation. A molybdenum nucleation layer is formed on a metal layer disposed within a damascene structure formed in a surface of a substrate maintained at a processing temperature of less than 425 degrees Celsius. The damascene structure includes a plurality of vias and the metal layer is disposed at a bottom surface of the plurality of vias. To form the molybdenum nucleation layer, a molybdenum-containing precursor (MCP) is delivered to the substrate for a first period of time. A reactive precursor gas is delivered to the substrate for the first period of time. A carrier gas is delivered to the substrate for a second period of time. The reactive precursor gas is delivered to the substrate for a third period of time. A molybdenum layer is deposited within the plurality of vias on the molybdenum nucleation layer.

### BACKGROUND

### Field

Embodiments described herein generally relate to molybdenum deposition. More specifically, embodiments of the present disclosure relate to molybdenum nucleation layer formation.

### Description of the Related Art

Integrated circuits have evolved into complex devices that can include millions of transistors, capacitors, and resistors on a single chip. In the course of integrated circuit evolution, functional density (that is, the number of interconnected devices per chip area) has generally increased while geometry size (that is, the smallest component (or line) that can be created using a fabrication process) has decreased.

Microelectronic devices are fabricated on a semiconductor substrate as integrated circuits in which various conductive layers are interconnected with one another to permit electronic signals to propagate within the device. Examples of such devices include memory (for example, DRAM (dynamic random access memory)) and logic devices, including both planar and three-dimensional structures. Three-dimensional structures include finFET (fin field-effect transistor) or MOSFET (metal-oxide-semiconductor field-effect transistor) devices.

In a traditional interconnect formation process, a feature also referred to a cavity, a via, or a trench, is fabricated in the semiconductor substrate. Interconnects allow connections between layers of an integrated circuit containing device. A low resistivity interconnect is desirable in semiconductor devices. However, when an interconnect has a high resistance the performance of the integrated circuit containing device.

Because of its material properties including high conductivity, molybdenum is a desirable material for multiple applications in semiconductor device manufacturing. However, depositing molybdenum on certain substrate materials at relatively low temperatures using a molybdenum-containing precursor (MCP) is challenging due to the corrosive nature the MCP. For example, if molybdenum is to be deposited on a copper substrate, the exposure to the MCP will cause corrosion of the exposed copper surfaces before the molybdenum is deposited thereon which creates corrosion products that are incorporated into the deposited layer and will adversely affect the performance of the formed interconnect.

Accordingly, there is a need in the art for a desirable technique that solves the problems described above.

### SUMMARY

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

Embodiments of the present disclosure provide a method that includes forming a molybdenum nucleation layer on a metal layer disposed within a damascene structure formed in a surface of a substrate. The damascene structure includes a plurality of vias and the metal layer is disposed at a bottom surface of the plurality of vias. To form the molybdenum nucleation layer, a.) a molybdenum-containing precursor (MCP) is delivered to the substrate maintained at a processing temperature of less than 425 degrees Celsius during a first period of time; b.) a reactive precursor gas is delivered to the substrate during the first period of time; c.) a carrier gas is delivered to the substrate during a second period of time; d.) the reactive precursor gas is delivered to the substrate during a third period of time; and a.) to d.) are repeated one or more times. A molybdenum layer is deposited within the plurality of vias on the molybdenum nucleation layer.

Embodiments of the present disclosure provide a method that includes forming a molybdenum nucleation layer on a metal layer disposed within a damascene structure formed in a surface of a substrate. The damascene structure includes a via and the metal layer is positioned at a bottom of surface of the via. To form the molybdenum nucleation layer, a.) a molybdenum-containing precursor (MCP) is delivered to the substrate maintained at a processing temperature of less than 425 degrees Celsius during a first period of time; b.) a carrier gas is delivered to the substrate during a second period of time; c.) reactive precursor gas is delivered to the substrate during a third period of time; d.) the carrier gas is delivered to the substrate during a fourth period of time; and a.) to d.) are repeated one or more times. A molybdenum layer is deposited within the via on the molybdenum nucleation layer.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic plan view of a multi-chamber substrate processing system, in accordance with certain embodiments of the present disclosure.

FIG. 2 is a process flow diagram illustrating a method for forming a molybdenum nucleation layer, in accordance with certain embodiments of the present disclosure.

FIGS. 3A and 3B are graphs illustrating example gas delivery inputs provided during different parts of a molybdenum nucleation layer formation process performed in one or more types of processing chambers, in accordance with certain embodiments of the present disclosure.

FIGS. 4A, 4B, 4C, and 4D are schematic cross-sectional views of a first example of depositing molybdenum, in accordance with certain embodiments of the present disclosure.

FIGS. 5A, 5B, 5C, and 5D are schematic cross-sectional views of a second example of depositing molybdenum, in accordance with certain embodiments of the present disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to molybdenum deposition processes. More specifically, embodiments of the present disclosure relate to molybdenum layer formation processes. In some embodiments, a substrate is disposed in a processing chamber such as a chemical vapor deposition (CVD) processing chamber, an atomic layer deposition (ALD) processing chamber, or another type of processing chamber. A plurality of damascene structures are formed in a surface of the substrate. In some embodiments, the damascene structures are single damascene structures. In other embodiments, the damascene structures are dual damascene structures.

The damascene structures include vias and trenches into which one or more metal layers are deposited. The vias and trenches are formed over an underlying interconnect layer, which comprises a conductive material such as a metal layer. In one or more embodiments, the underlying interconnect layer comprises a copper layer. In some embodiments, the underlying interconnect layer comprises a copper containing layer capped with a cobalt containing layer.

In some embodiments, the processing temperature of the substrate during processing within a processing chamber is relatively low. In some embodiments, a substrate processing temperature of less than or equal to 425 degrees Celsius is maintained within the processing chamber during processing. In order to deposit molybdenum on the underlying interconnect layer (e.g., the metal layer) at the relatively low temperature, a molybdenum-containing precursor (MCP) such as MoCl₅ is injected/delivered into the processing chamber. In some embodiments, a hydrogen containing precursor can also be co-flowed with the MCP into the processing chamber during processing. In other embodiments, the hydrogen containing precursor is flowed/delivered into the processing chamber after injecting/delivering the MCP into the processing chamber.

A molybdenum nucleation layer is formed on the underlying interconnect layer based on the MCP and the hydrogen without damaging the material within the underlying interconnect layer. A molybdenum layer is then deposited on the molybdenum nucleation layer within the vias and trenches of the damascene structures formed in the surface of the substrate. In some embodiments, an additional conductive layer such as an additional copper containing layer is deposited on the molybdenum layer to at least partially fill the damascene structure.

### Multi-Chamber Processing System Examples

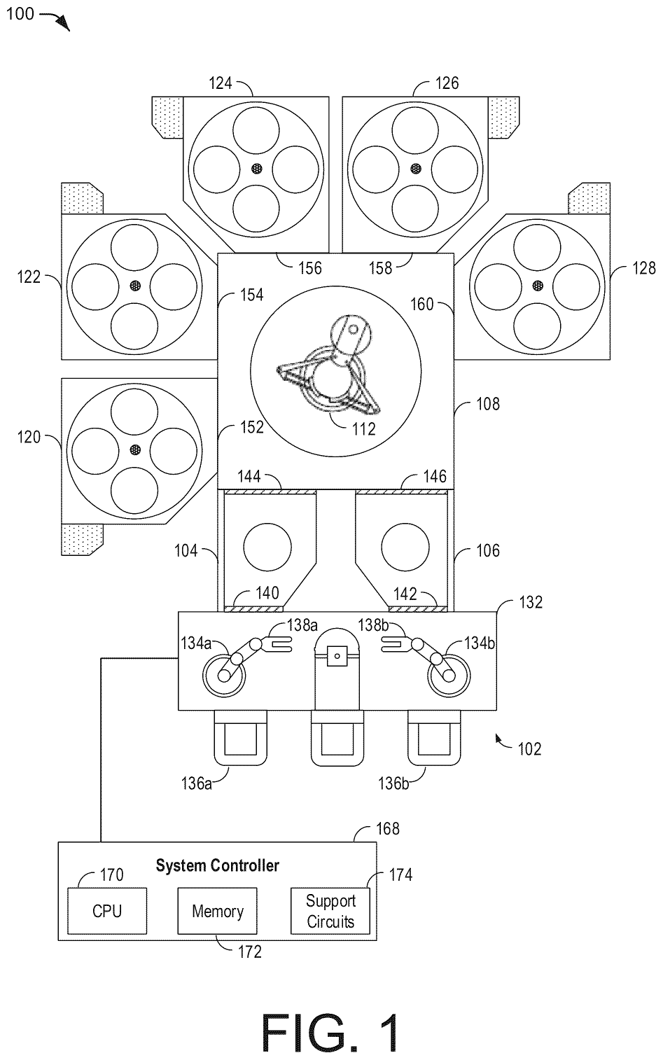

FIG. 1 is a schematic plan view of a multi-chamber substrate processing system 100. The substrate processing system 100 is capable of depositing a seamless fill of molybdenum from the bottom of a feature, upward to the top of the feature, without breaking vacuum. The substrate processing system 100 generally includes a factory interface 102, load lock chambers 104, 106, transfer chambers 108, a transfer robot 112, and processing chambers 120, 122, 124, 126, and 128.

Substrates in the substrate processing system 100 can be processed in and transferred between the various chambers without exposing the substrates to an ambient environment that is exterior to the substrate processing system 100. Furthermore, the substrates can be processed in and transferred between the various chambers maintained at a low pressure, or a vacuum environment without breaking the low pressure or vacuum environment. The substrate processing system 100 is capable of maintaining pressures between about 0.01 Torr to about 760 Torr. Accordingly, the substrate processing system 100 may provide for an integrated solution for processing of substrates.

Alternate examples of processing systems that may be suitably modified in accordance with the teachings provided herein include the Endura®, Producer®, or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In FIG. 1, the factory interface 102 includes a docking station 132 and factory interface robots 134a, 134b to facilitate transfer of substrates. The docking station 132 is configured to accept one or more front opening unified pods (FOUPs) 136a, 136b. In some examples, the factory interface robots 134a, 134b include blades 138a, 138b, respectively. The blades 138a, 138b are configured to transfer the substrates from the factory interface 102 to the load lock chambers 104, 106.

The load lock chambers 104, 106 have ports 140, 142, respectively, coupled to the factory interface 102 and ports 144, 146, respectively, coupled to the transfer chamber 108. The transfer chamber 108 includes ports 152, 154, 156, 158,160 coupled to processing chambers 120, 122, 124, 126, 128, respectively. The ports 144, 146, 152, 154, 156, 158, 160 can be slit valve openings with slit valves for passing substrates through by the transfer robot 112. The ports 144, 146, 152, 154, 156, 158, 160 are configured to provide seals between respective chambers to prevent gases from passing between the respective chambers.

The load lock chambers 104, 106, the transfer chamber 108, and the processing chambers 120, 122, 124, 126, 128 may be fluidly coupled to a gas and pressure control system (not shown). The gas and pressure control system can include one or more gas pumps (e.g., turbo pumps, cryo-pumps, roughing pumps, etc.) gas sources, various valves, and conduits fluidly coupled to the load lock chambers 104, 106, the transfer chamber 108, and the processing chambers 120, 122, 124, 126, 128. In operation, the factory interface robots 134a, 134b transfer substrates from the FOUPs 136a, 136b through the ports 140, 142 to the load lock chambers 104, 106. The gas and pressure control system then pumps down the load lock chambers 104, 106. The gas and pressure control system further maintains the transfer chamber 108 with an interior low pressure or vacuum environment (which may include an inert gas). Hence, the pumping down of the load lock chambers 104, 106 facilitates passing substrates between, for example, the atmospheric environment of the factory interface 102 and the low pressure or vacuum environment of the transfer chamber 108.

With substrates in the load lock chambers 104, 106 that have been pumped down, the transfer robot 112 transfers the substrates from the load lock chambers 104, 106 into the transfer chamber 108 through the ports 144, 146. The transfer robot 112 is then capable of transferring the substrates to and/or between any of the processing chambers 120, 122, 124, 126, 128 through the ports 152, 154, 156, 158, 160, respectively, for processing. The transfer of the substrates within and among the various chambers can be in the low pressure or vacuum environment provided by the gas and pressure control system.

The processing chambers 120, 122, 124, 126, 128 include multiple processing stations disposed within a common processing region. The processing chambers 120, 122, 124, 126, 128 can be any appropriate chamber for processing a substrate. In some examples, the processing chamber 120 can be capable of performing an etch process, the processing chamber 122 can be capable of performing a cleaning process, and the processing chambers 126, 128 can be capable of performing respective growth (e.g., deposition) processes. The processing chamber 120 may be a Selectra™ Etch chamber available from Applied Materials of Santa Clara, California. The processing chamber 122 may be a SiCoNi™ Pre-clean chamber available from Applied Materials of Santa Clara, California. The processing chamber 126, or 128, may be a Volta™ CVD/ALD chamber, or Encore™ PVD chambers available from Applied Materials of Santa Clara, California.

A system controller 168 is coupled to the substrate processing system 100 for controlling the substrate processing system 100 or components thereof. For example, the system controller 168 may control the operation of the substrate processing system 100 using a direct control of the processing chambers 120, 122, 124, 126, 128 of the substrate processing system 100 or by controlling controllers associated with the processing chambers 120, 122, 124, 126, 128. In operation, the system controller 168 enables data collection and feedback from the respective chambers to coordinate performance of the substrate processing system 100.

The system controller 168 generally includes one or more processors such as a central processing unit (CPU) 170, memory 172, and support circuits 174. The CPU 170 may be one of any form of a general-purpose processor that can be used in an industrial setting. In some embodiments, the memory 172 includes one or more non-transitory computer readable media storing executable instructions that, when executed by a processor, (such as the CPU 170) causes the processor to perform operations. The memory 172 is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. That is, the computer program product is tangibly embodied on the memory 172 (or non-transitory computer-readable medium or machine-readable storage device). When the computer instruction code is executed by the CPU 170, the CPU 170 controls the chambers to perform processes in accordance with the various methods.

The instructions in memory 172 may be in the form of a program product, such as a program that implements the methods of the present disclosure. In one example, the disclosure may be implemented as a program product stored on a computer-readable storage media for use with a computer system. The program(s) of the program product define functions of the embodiments (including the methods described herein). Thus, the computer-readable storage media, when carrying computer-readable instructions that direct the functions of the methods described herein, are embodiments of the present disclosure.

In particular embodiments, at least one of the processing chambers 120, 122 is a pre-clean chamber, at least one of the processing chambers 124, 126, 128 is a chemical vapor deposition (CVD) chamber, and at least one of the processing chambers 124, 126, 128 is an atomic layer deposition (ALD) chamber. In operation, a substrate having a feature formed therein may be transferred to a first processing chamber which is one of the processing chambers 122, 124 where the feature is exposed to a pretreatment process to remove, or clean, for example, native oxides formed on the feature. The substrate may then be transferred to a second processing chamber which is one of the processing chambers 124, 126, 128 without breaking vacuum where a metal layer, for example, a molybdenum layer, is deposited over the feature. The substrate may then be transferred to a third processing chamber without breaking vacuum for additional processing. Other processing systems can be implemented in various embodiments.

### Processing Examples

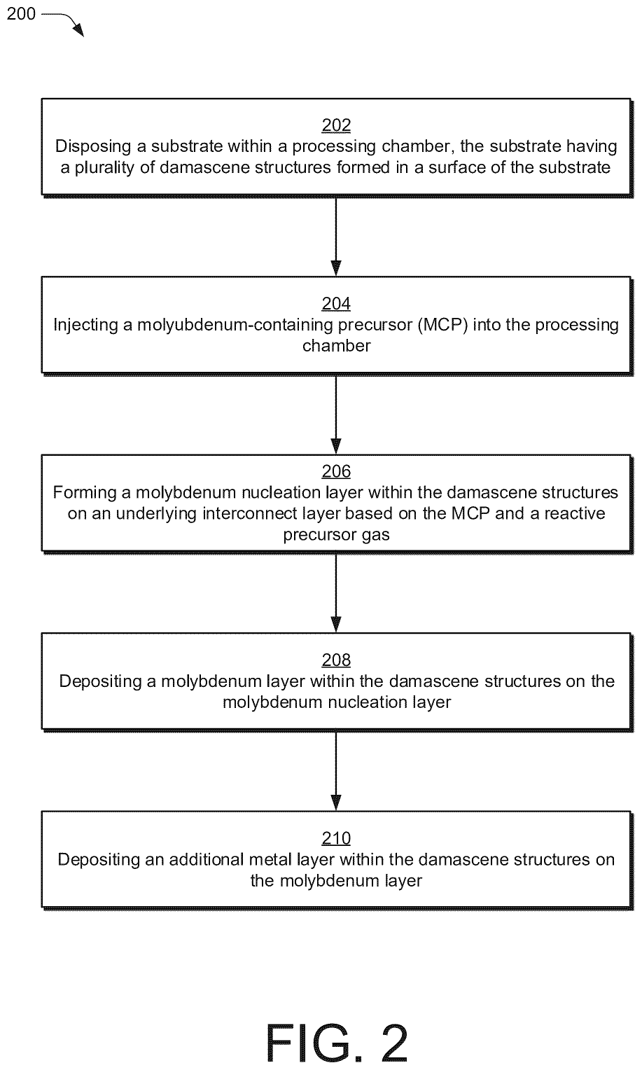

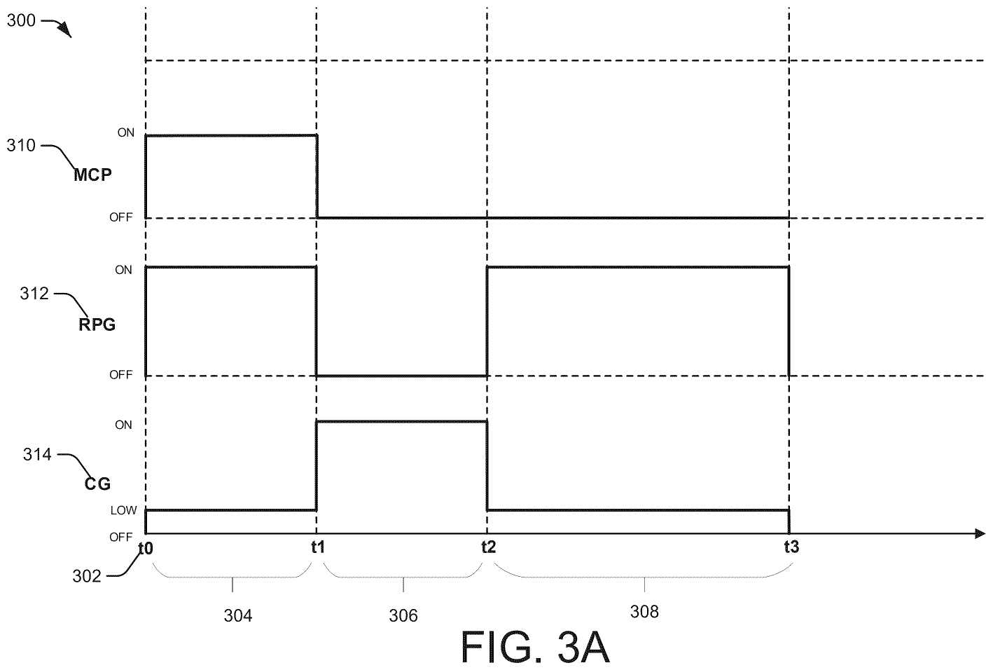

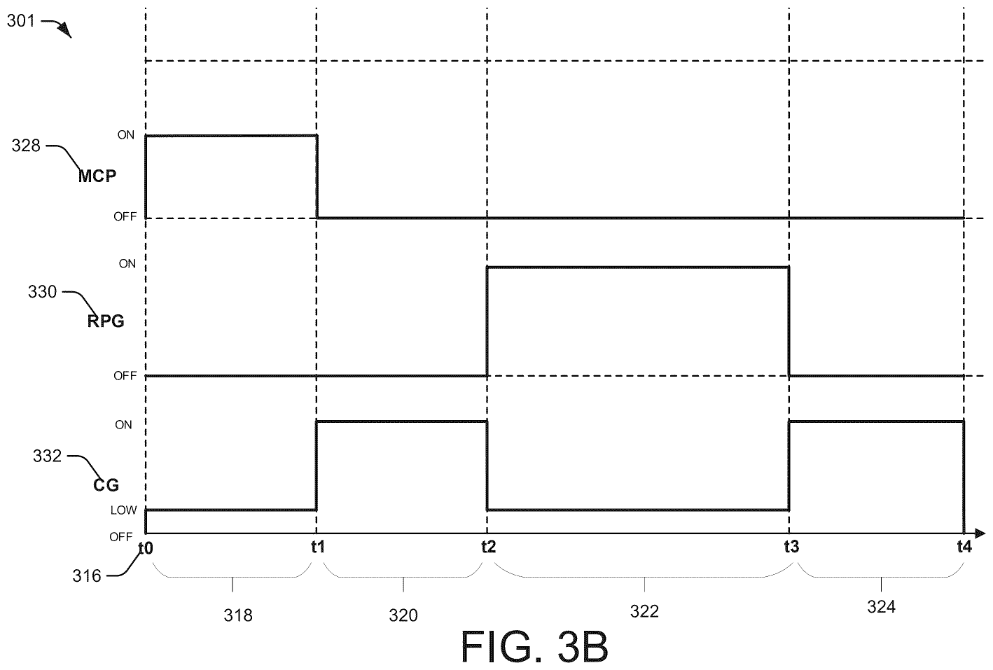

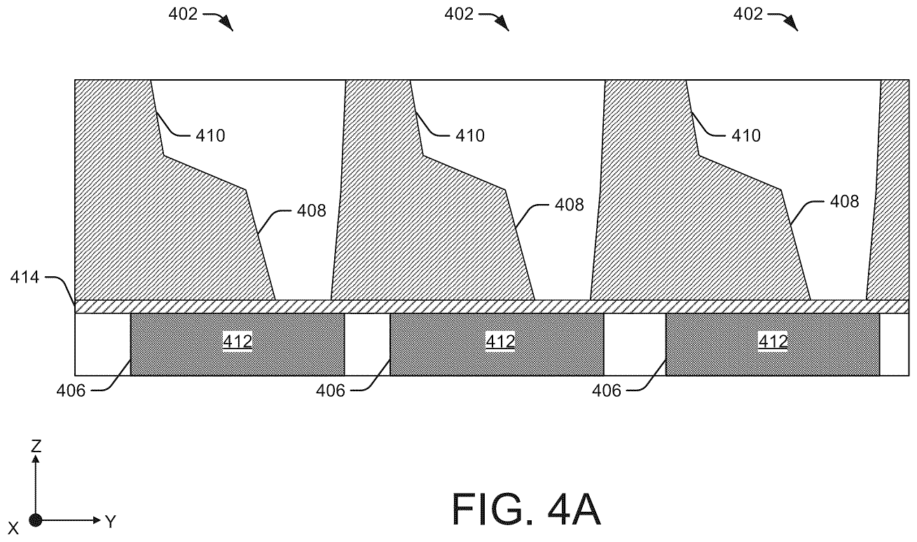

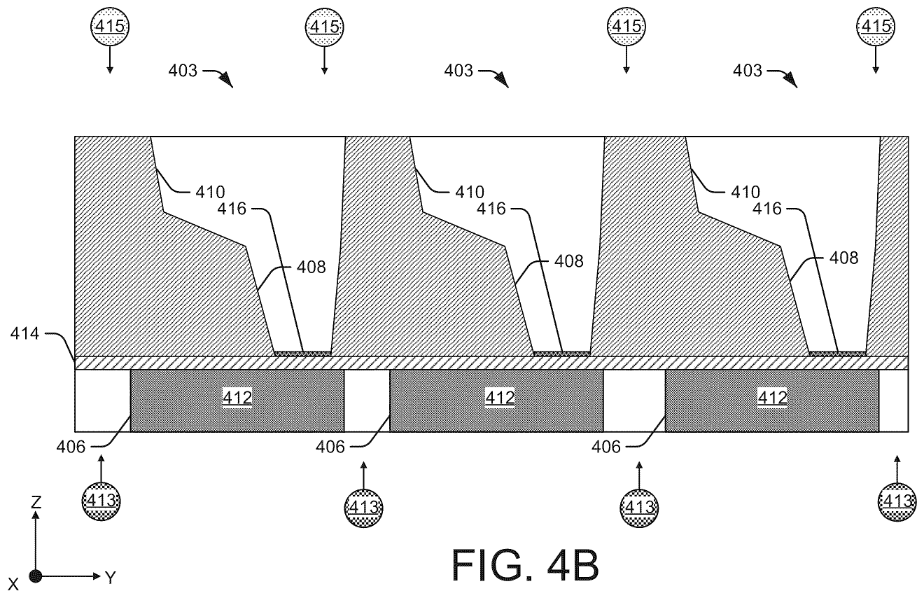

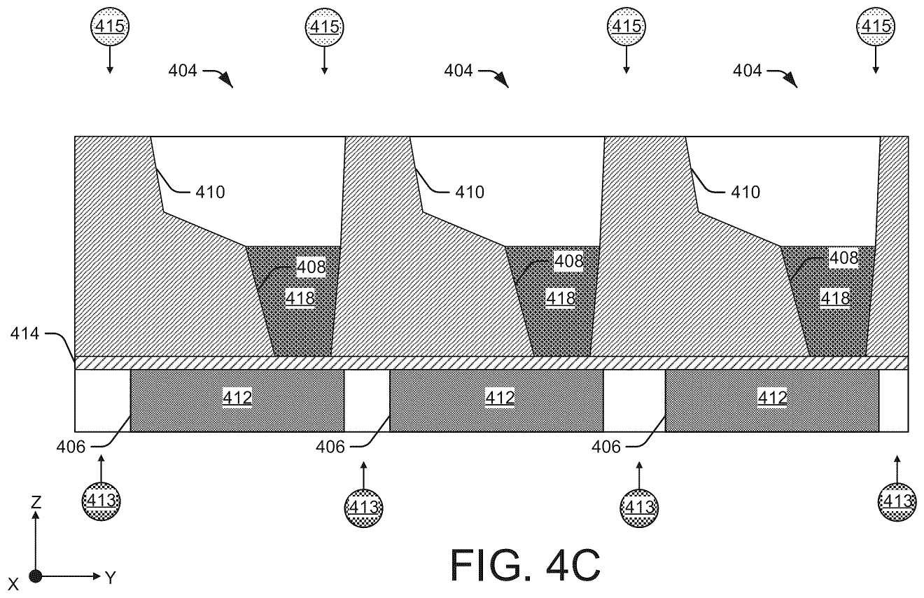

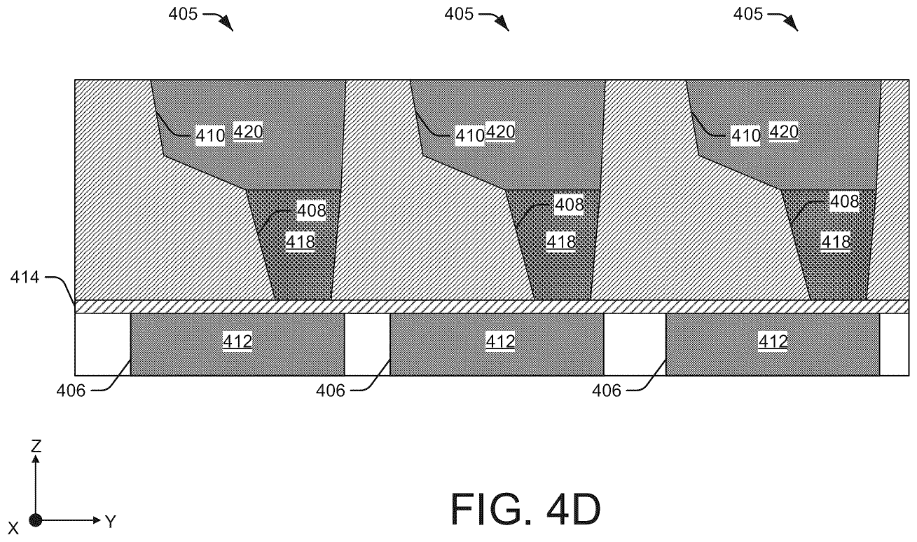

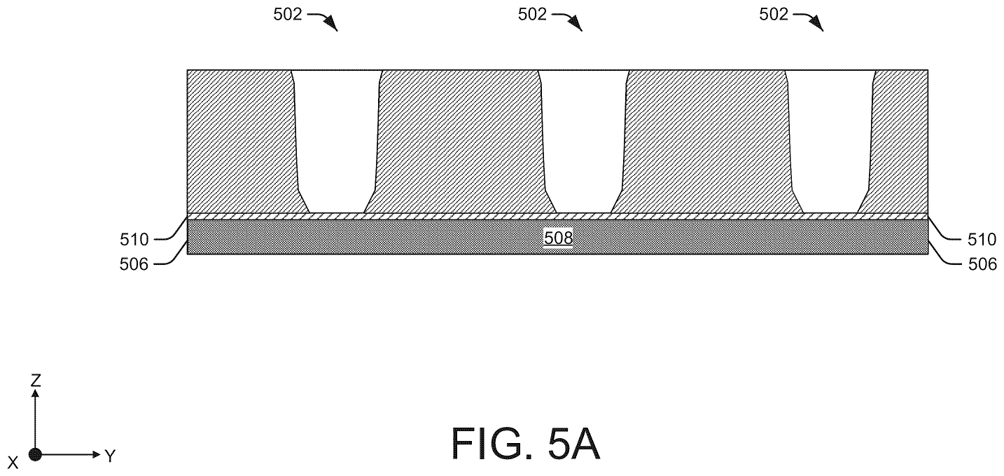

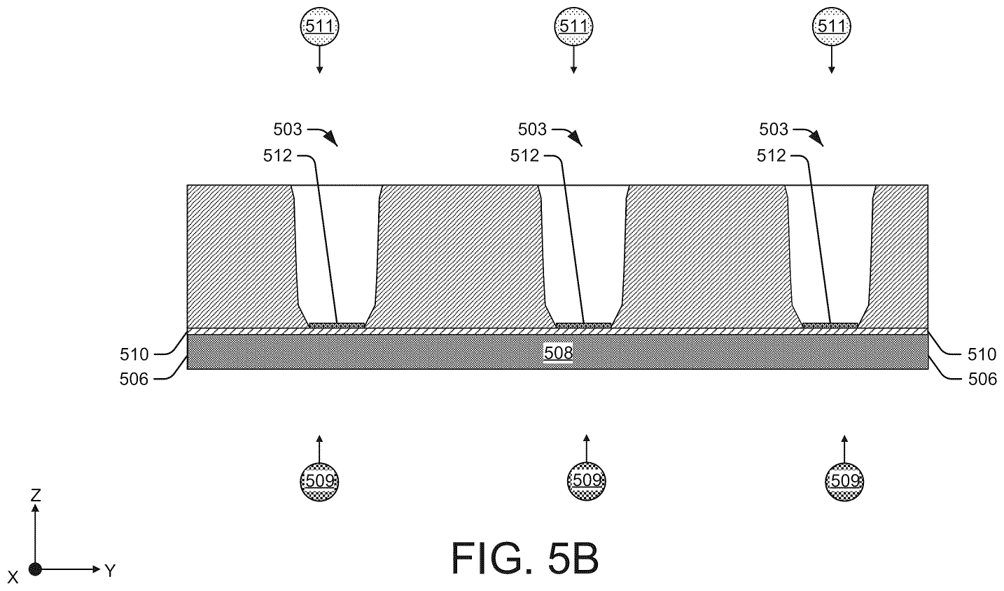

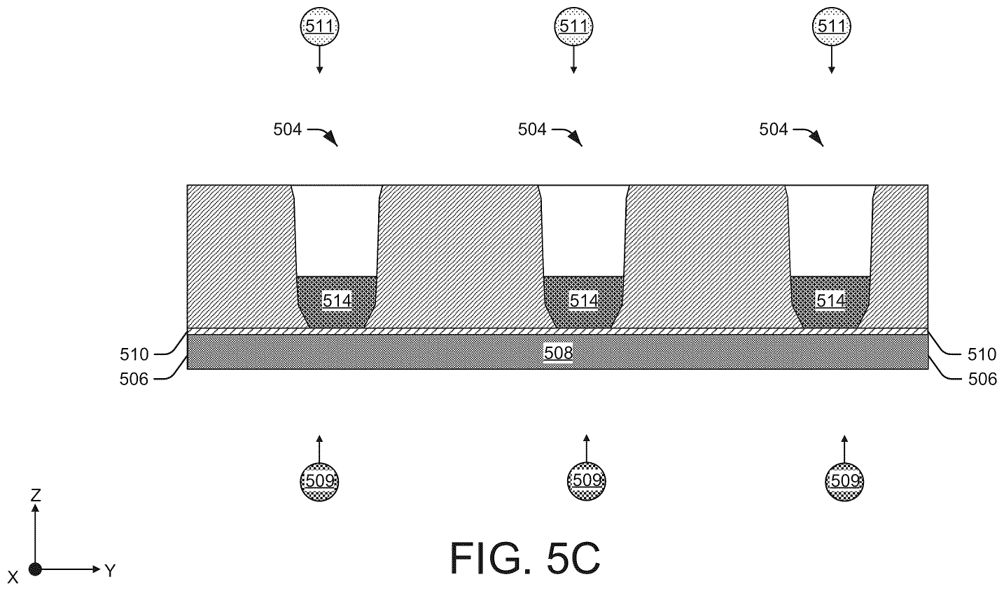

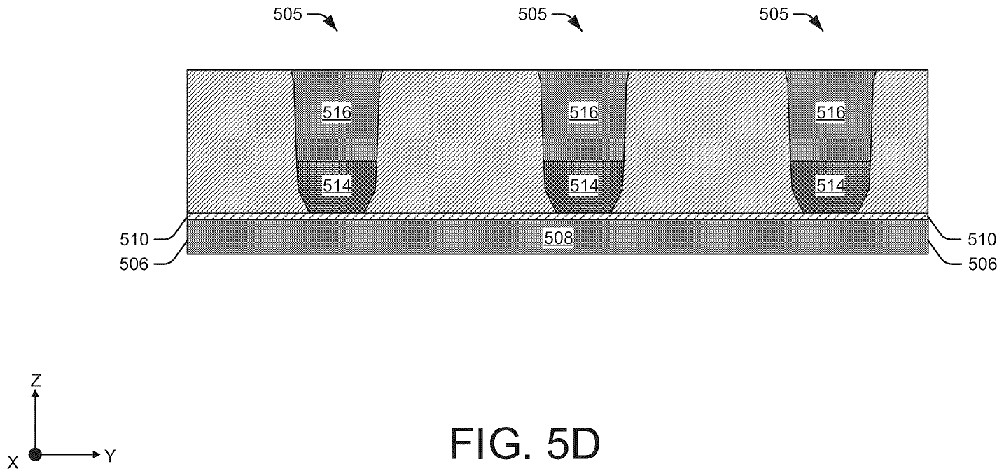

FIG. 2 is a process flow diagram illustrating a method 200 for forming a molybdenum nucleation layer. FIGS. 3A and 3B are graphs illustrating example gas delivery inputs provided during different parts of a molybdenum nucleation layer formation process performed in one or more types of processing chambers. FIGS. 4A, 4B, 4C, and 4D are schematic cross-sectional views of a first example of depositing molybdenum. FIGS. 5A, 5B, 5C, and 5D are schematic cross-sectional views of a second example of depositing molybdenum.

With reference to FIG. 2, at operation 202, a substrate is disposed within a processing chamber, the substrate having a plurality of damascene structures formed in a surface of the substrate. FIG. 4A illustrates a schematic cross-sectional view of damascene structures 402 formed in a surface of a substrate disposed in one of the processing chambers 124, 126, 128. The damascene structures 402 extend into the substrate in the Z-direction with features formed within the substrate in the X-direction and the Y-direction. In some embodiments, the damascene structures 402 are dual damascene structures. In other embodiments, the damascene structures 402 are single damascene structures.

The damascene structures 402 each include a via 408 and an upper trench 410. As shown, a layer 412 (e.g., a metal layer) of an underlying interconnect layer is formed below the vias 408. In some embodiments, the layer 412 includes a copper layer or a cobalt layer. In other embodiments, the layer 412 includes a layer of another material. A capping layer 414 of the underlying interconnect layer is deposited over the layer 412 below the vias 408. In one or more embodiments, the capping layer 414 includes a cobalt layer. In some embodiments, the capping layer 414 includes a layer of another material.

FIG. 5A illustrates a schematic cross-sectional view of damascene structures 502 formed in a surface of a substrate disposed in one of the processing chambers 124, 126, 128. The damascene structures 502 extend into the substrate in the Z-direction and the damascene structures include features formed within the substrate in the X-direction and the Y-direction. As shown, a layer 508 (e.g., a metal layer) of an underlying interconnect layer is deposited below the damascene structures 502. In some embodiments, the layer 508 includes a copper layer, a cobalt layer, or a layer of another material. A capping layer 510 of the underlying interconnect layer is deposited over the layer 508. In one or more embodiments, the capping layer 510 includes a cobalt layer or a layer of another material.

With reference to FIG. 2, at operation 204, a molybdenum-containing precursor (MCP) is injected into the processing chamber. FIG. 3A illustrates a graph 300 of example gas delivery inputs for forming molybdenum nucleation layers in a chemical vapor deposition (CVD) processing chamber. The x-axis of the graph 300 includes an initial time 302, a first period of time 304, a second period of time 306, and a third period of time 308. The y-axis of the graph 300 illustrates the “on” and “off” times for each of the gas delivery inputs to an example CVD processing chamber such as a molybdenum-containing precursor (MCP) 310, a reactive precursor gas (RPG) 312 (e.g., hydrogen gas), and a carrier gas (CG) 314 (e.g., argon gas). The MCP 310 may include MoCl₅ or another molybdenum-containing precursor. During an “on” time the amount of one of the provided gases may be varied as illustrated in FIG. 3A by the differing levels of the carrier gas 314 flow between times t0 and t3, wherein the gas flows between times t0 and t1 (i.e., during the first period of time 304) and between times t2 and t3 (i.e., during the third period of time 308) are less than the gas flow between times t1 and t2 (i.e., during the second period of time 306). For example, during the “on” time, the carrier gas 314 flow is “low” during the first period of time 304 and during the third period of time 308.

In various embodiments, a processing temperature within the processing chamber is maintained in a range of about 325 to 425 degrees Celsius (C) such as about 350° C., 400° C., etc. In some embodiments, an ampoule temperature of an ampoule (e.g., housing the MCP 310), which positioned upstream of the processing chamber environment, is maintained at a lower temperature than the temperature of the substrate disposed within the processing chamber. In one or more examples, the ampoule temperature may be maintained in a range of about 60 to 90° C. In certain embodiments, a pressure within the processing chamber may be maintained in a range of about 5 to 50 Torr.

In the example illustrated in FIG. 3A, during the first period of time 304, carrier gas 314 is flowed into the processing chamber (e.g., the carrier gas 314 flow is “low”). In some embodiments, carrier gas 314 may be flowed into the processing chamber at a rate in a range of about 0.1 to 12000 standard cubic centimeters per minute (sccm). In other embodiments, carrier gas 314 may not be flowed into the processing chamber during the first period of time 304.

In one or more embodiments, reactive precursor gas 312 is flowed into the processing chamber during the first period of time 304. In certain embodiments, reactive precursor gas 312 can be flowed into the processing chamber at a rate in a range of about 0.1 to 21000 sccm. In various embodiments, reactive precursor gas 312 may not be flowed into the processing chamber during the first period of time 304.

In some embodiments, during the first period of time 304, the MCP 310 is injected into the processing chamber. For example, the MCP 310 is injected into the processing chamber and the reactive precursor gas 312 is flowed into the processing chamber concurrently during the first period of time 304. In one or more examples, the MCP 310 is injected into the processing chamber at a rate in a range of about 50 to 2000 sccm during the first period of time 304. In certain embodiments, the first period of time 304 can be a period of time that includes a range of time between about 5 to 60 seconds, such as about 30 seconds.

As shown in the example in the graph 300, during the second period of time 306, the injection of the MCP 310 into the processing chamber is halted. Additionally, in some embodiments, at time t1 (which is the end of the first period of time 304), the flow of reactive precursor gas 312 into the processing chamber is halted. In various examples, the flow of carrier gas 314 into the processing chamber is increased during the second period of time 306 relative to the flow of carrier gas 314 during the first period of time. In some embodiments, during the second period of time 306, carrier gas 314 is flowed into the processing chamber at a rate in a range of 3000 to 12000 sccm. In one or more embodiments, the second period of time 306 can be a period of time that includes a range of time between about 5 to 60 seconds, such as about 30 seconds.

In some examples, during the third period of time 308, the injection of the MCP 310 into the processing chamber remains halted. In one or more examples, at the second period of time 306, the flow of carrier gas 314 into the processing chamber is decreased or halted. In some embodiments, carrier gas 314 may be flowed into the processing chamber at a rate in a range of about 0.1 to 12000 during the third period of time 308. In other embodiments, carrier gas 314 may not be flowed into the processing chamber during the third period of time 308.

As shown, at time t2 (which is the end of the second period of time 306), reactive precursor gas 312 is flowed into the processing chamber. In one or more examples, carrier gas 314 is flowed into the processing chamber before and after reactive precursor gas 312 is flowed into the processing chamber. In certain embodiments, during the third period of time 308, reactive precursor gas 312 is flowed into the processing chamber at a rate in a range of 1000 to 21000 sccm. In one or more embodiments, the third period of time 308 may be a period of time that includes a range of time between about 5 to 120 seconds, such as about 90 seconds.

FIG. 3B illustrates a graph 301 of example inputs for forming molybdenum nucleation layers in atomic layer deposition (ALD) processing chambers. The x-axis of the graph 301 includes an initial time 316, a first period of time 318, a second period of time 320, a third period of time 322, and a fourth period of time 324 of one cycle. The y-axis of the graph 301 illustrates the “on” and “off” times for each of the gas delivery inputs to an example ALD processing chamber such as a molybdenum-containing precursor (MCP) 328, a reactive precursor gas (RPG) 330 (e.g., hydrogen gas), and a carrier gas (CG) 332 (e.g., argon gas). The MCP 228 may include MoCl₅ or another molybdenum-containing precursor. During an “on” time the amount of one of the provided gases may be varied as illustrated in FIG. 3B by the differing levels of the carrier gas 332 flow between times to and t2, wherein the gas flow during time to and t1 (i.e., during the first period of time 318) is less than the gas flow during times t1 and t2 (i.e., during the second period of time 320). In some examples, during the “on” time, the carrier gas 332 flow is “low” during the first period of time 318.

In various embodiments, a processing temperature within the processing chamber is maintained in a range of about 325 to 425° C. such as about 350° C., 400° C., etc. In some embodiments, an ampoule temperature of an ampoule (e.g., housing the MCP 328), which positioned upstream of the processing chamber environment, is maintained at a lower temperature than the temperature within the processing chamber. For example, the ampoule temperature may be maintained in a range of about 60 to 90° C. In certain embodiments, a pressure within the processing chamber may be maintained in a range of about 5 to 50 Torr.

As shown, during the first period of time 318, the MCP 328 is injected into the processing chamber at a rate in a range of about 50 to 2000 sccm. For example, the MCP 328 is pulsed into the processing chamber during the first period of time 318. The carrier gas 232 may or may not flow into the processing chamber during the first period of time 318. In some embodiments, the first period of time 318 can include a period of time in a range of about 0.3 to 4 seconds such as about 1 second.

In one or more embodiments, at time t1 (which is the end of the first period of time 318), the injection of the MCP 328 into the processing chamber is halted. During the second period of time 320, the carrier gas 332 is flowed into the processing chamber. In certain embodiments, the carrier gas 332 is pulsed into the processing chamber during the second period of time 320 to remove a gas phase of the MCP 328 in the processing chamber. In some embodiments, the second period of time 320 can include a period of time in a range of about 0.3 to 4 seconds such as about 1 second.

As shown in the graph 301, at time t2 (which is the end of the second period of time 320), the flow of the carrier gas 332 into the processing chamber is halted. In various embodiments, during the third period of time 322, the reactive precursor gas 330 is flowed into the processing chamber. For example, the MCP 328 is injected into the processing chamber and the reactive precursor gas 330 is flowed into the processing chamber separately. In some examples, the reactive precursor gas 330 is flowed into the processing chamber at a rate in a range of 1000 to 21000 sccm. The third period of time 322 may include a period of time in a range of about 0.3 to 4 seconds such as about 3 seconds.

In some embodiments, at time t3 (which is the end of the third period of time 322), the flow of the reactive precursor gas 330 into the processing chamber is halted. During the fourth period of time 324, the carrier gas 332 is flowed into the processing chamber. In certain embodiments, the carrier gas 332 is pulsed into the processing chamber during the fourth period of time 324 to purge the reactive precursor gas 330. In some embodiments, the fourth period of time 324 can include a period of time in a range of about 0.3 to 4 seconds such as about 1 second.

With reference to FIG. 2, at operation 206, a molybdenum nucleation layer is formed within the damascene structures on an underlying interconnect layer based on the MCP and a reactive precursor gas. Referring to FIG. 3A, at the end of the third period of time 308, the injection of the MCP 310 into the processing chamber remains halted, the flow of reactive precursor gas 312 into the processing chamber is halted, and the flow of carrier gas 314 into the processing chamber is halted. In some embodiments, at the end of the third period of time 308, a molybdenum nucleation layer has formed on an underlying interconnect layer formed on a substrate disposed in the processing chamber. In one or more embodiments, the underlying interconnect layer may be a copper layer, a cobalt layer, or a layer of another material.

Referring to FIG. 3B, at time t4 (which is the end of the fourth period of time 324), the flow of the carrier gas 332 into the processing chamber is halted and one cycle is complete. After the cycle is complete, another cycle begins at the initial time 316 (i.e., at time t0). In some embodiments, the number of cycles performed is in a range of about 10 to 50 cycles such as about 30 cycles. In one or more embodiments, after performing the cycles, a molybdenum nucleation layer has formed on an underlying interconnect layer (e.g., a metal layer) within damascene structures formed in a surface of a substrate disposed in the processing chamber. In certain embodiments, the underlying interconnect layer can be a copper layer, a cobalt layer, or a layer of another material.

FIG. 4B illustrates a schematic cross-sectional view of damascene structures 403 formed in the surface of the substrate having a molybdenum nucleation layer 316 formed on the capping layer 314 of the underlying interconnect layer. As shown, a molybdenum-containing precursor (MCP) 413 is injected into the one of the processing chambers 124, 126, 128 that includes the substrate and a reactive precursor gas 415 (e.g., hydrogen gas) is flowed into the one of the processing chambers 124, 126, 128 that includes the substrate. In an example in which the one of the processing chambers 124, 126, 128 is a chemical vapor deposition (CVD) processing chamber, then the MCP 413 may be injected and the reactive precursor gas 415 may be flowed as described with respect to FIG. 3A. In an example in which the one of the processing chambers 124, 126, 128 is an atomic layer deposition (ALD) processing chamber, then the MCP 413 may be injected and the reactive precursor gas 415 may be flowed as described with respect to FIG. 3B. As illustrated in FIG. 4B, the molybdenum nucleation layer 416 is formed within the vias 403. Although the molybdenum nucleation layer 416 is illustrated to be formed selectively within bottoms of the vias 403, in some embodiments, the molybdenum nucleation layer 416 may be formed non-selectively such that the molybdenum nucleation layer 416 is formed on sidewalls of the vias 403 and on a field region that separates the vias 403 in addition to the bottoms of the vias 403.

FIG. 5B illustrates a schematic cross-sectional view of damascene structures 503 formed in the surface of the substrate having a molybdenum nucleation layer 512 formed on the capping layer 410 of the underlying interconnect layer. In various embodiments, a molybdenum-containing precursor (MCP) 409 such as MoCl₅ is injected into the one of the processing chambers 124, 126, 128 that includes the substrate and a reactive precursor gas 511 (e.g., hydrogen gas) is flowed into the one of the processing chambers 124, 126, 128 that includes the substrate. In an example in which the one of the processing chambers 124, 126, 128 is a chemical vapor deposition (CVD) processing chamber, then the MCP 509 may be injected and the reactive precursor gas 511 may be flowed as described with respect to FIG. 3A. In an example in which the one of the processing chambers 124, 126, 128 is an atomic layer deposition (ALD) processing chamber, then the MCP 509 may be injected and the reactive precursor gas 511 may be flowed as described with respect to FIG. 3B. As shown in FIG. 5B, the molybdenum nucleation layer 512 is formed within the vias 503. Although the molybdenum nucleation layer 512 is illustrated to be formed selectively within bottoms of the vias 503, in some embodiments, the molybdenum nucleation layer 512 may be formed non-selectively such that the molybdenum nucleation layer 512 is formed on sidewalls of the vias 503 and on a field region that separates the vias 503 in addition to the bottoms of the vias 503.

With reference to FIG. 2, at operation 208, a molybdenum layer is deposited within the damascene structures on the molybdenum nucleation layer. Referring to FIG. 3A, after the molybdenum nucleation layer has formed, a layer of molybdenum can be deposited on the molybdenum nucleation layer. In some embodiments, in order to deposit the layer of molybdenum, the processing temperature of the processing chamber is maintained in a range of about 325 to 425° C.; the pressure within the processing chamber is maintained in a range of about 5 to 30 Torr, the ampoule temperature is maintained in a range of about 60 to 90° C.; and reactive precursor gas 312 is flowed into the processing chamber at a rate in a range of about 7000 to 21000 sccm. The MCP 310 is also injected into the processing chamber. In some embodiments, the sequence gas delivery inputs provided between t0, t1, t2, and t3 are repeated one or more times.

Referring to FIG. 3B, after the molybdenum nucleation layer has formed, a layer of molybdenum can be deposited on the molybdenum nucleation layer. In some embodiments, in order to deposit the layer of molybdenum, the processing temperature of the processing chamber is maintained in a range of about 325 to 425° C.; the pressure within the processing chamber is maintained in a range of about 5 to 30 Torr, the ampoule temperature is maintained in a range of about 60 to 90° C.; and reactive precursor gas 330 is flowed into the processing chamber at a rate in a range of about 7000 to 21000 sccm. The MCP 328 is also injected into the processing chamber.

FIG. 4C illustrates a schematic cross-sectional view of damascene structures 404 having a molybdenum layer 418 deposited within the damascene structures 404 on the molybdenum nucleation layer 416. After forming the molybdenum nucleation layer 416, the MCP 413 is injected into the processing chamber and the reactive precursor gas 415 (e.g., hydrogen gas) is flowed into the processing chamber to deposit the molybdenum layer 418 within the vias 408. In the illustrated example, the molybdenum layer 318 is deposited on the capping layer 414 (e.g., the cobalt layer) of the underlying interconnect layer. However, in other examples, the molybdenum layer 418 is deposited on the layer 412 (e.g., the copper layer) of the underlying interconnect layer. In some embodiments, the molybdenum layer 418 is electrically coupled to the layer 412. In one or more embodiments, a portion of the capping layer 414 may be removed as part of forming the molybdenum nucleation layer 416 which allows the molybdenum layer 418 to electrically couple to the layer 412. Notably, the electrical connection between the molybdenum layer 418 and metal layer 412 is established without damaging the layer 412.

FIG. 5C illustrates a schematic cross-sectional view of damascene structures 504 having a molybdenum layer 514 deposited within the damascene structures 504 on the molybdenum nucleation layer 512. After forming the molybdenum nucleation layer 512, the MCP 509 is injected into the processing chamber and the reactive precursor gas 511 (e.g., hydrogen gas) is flowed into the processing chamber to deposit the molybdenum layer 514 within the damascene structures 504. The molybdenum layer 514 may be deposited on the capping layer 510 (e.g., the cobalt layer) of the underlying interconnect layer. The molybdenum layer 514 can also be deposited directly on the layer 508 (e.g., the copper layer) of the underlying interconnect layer. In some embodiments, the molybdenum layer 514 is electrically coupled to the layer 508 without damaging the layer 508 or another portion of the substrate. In some embodiments, a portion of the capping layer 510 may be removed as part of forming the molybdenum nucleation layer 512 which allows the molybdenum layer 514 to electrically couple to the layer 508.

With reference to FIG. 2, at operation 210, an additional metal layer is deposited within the damascene structures on the molybdenum layer. FIG. 4D illustrates a schematic cross-sectional view of damascene structures 405 having an additional metal layer 420 deposited within the damascene structures 405 on the molybdenum layer 418. In some embodiments, the additional metal layer 420 includes a copper layer. In various embodiments, the molybdenum layer 418 electrically connects the layer 412 of the underlying interconnect layer and the additional metal layer 420. In one or more embodiments, the molybdenum layer 418 establishes the electrical connection between the layer 412 and the additional metal layer 420 without damaging the layer 412 or another portion of the substrate.

FIG. 5D illustrates a schematic cross-sectional view of damascene structures 505 having an additional metal layer 516 deposited within the damascene structures 505 on the molybdenum layer 514. In some embodiments, the additional metal layer 516 includes a copper layer. In various embodiments, the molybdenum layer 514 electrically connects the layer 508 of the underlying interconnect layer and the additional metal layer 516. In one or more embodiments, the molybdenum layer 514 establishes the electrical connection between the layer 508 and the additional metal layer 516 without damaging the layer 508 or another portion of the substrate.

### Additional Considerations

In the above description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or processes described with respect to one implementation may be combined with the features, components, and/or processes described with respect to other implementations of the present disclosure. As used herein, the term “about” may refer to a +/−10% variation from the nominal value. It is to be understood that such a variation can be included in any value provided herein.

As used herein, “a processor,” “at least one processor” or “one or more processors” generally refers to a single processor configured to perform one or multiple operations or multiple processors configured to collectively perform one or more operations. In the case of multiple processors, performance of the one or more operations could be divided amongst different processors, though one processor may perform multiple operations, and multiple processors could collectively perform a single operation. Similarly, “a memory,” “at least one memory” or “one or more memories” generally refers to a single memory configured to store data and/or instructions, multiple memories configured to collectively store data and/or instructions.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more operations or actions for achieving the described method. The method operations and/or actions may be interchanged with one another without departing from the scope of the claims. In other words, unless a specific order of operations or actions is specified, the order and/or use of specific operations and/or actions may be modified without departing from the scope of the claims.

While the foregoing is directed to embodiments of the present disclosure, other and further embodiments of the disclosure may be devised without departing from the basic scope thereof, and the scope thereof is determined by the claims that follow.

We claim:

1. A method of forming a molybdenum containing layer on a surface of a substrate, comprising:
forming a molybdenum nucleation layer on a metal layer disposed within a damascene structure formed in a surface of a substrate, wherein the damascene structure comprises a plurality of vias and the metal layer is positioned at a bottom surface of the plurality of vias, and forming the molybdenum nucleation layer comprises:
a.) delivering, during a first period of time, a molybdenum-containing precursor (MCP) to the substrate maintained at a processing temperature of less than 425 degrees Celsius;
b.) delivering, during the first period of time, a reactive precursor gas to the substrate;
c.) delivering, during a second period of time, a carrier gas to the substrate; and
d.) delivering, during a third period of time, the reactive precursor gas to the substrate; and
e.) repeating a.) to d.) one or more times; and
depositing, within the plurality of vias, a molybdenum layer on the molybdenum nucleation layer.

2. The method of claim 1, wherein the first period of time is in a range of 5 to 60 seconds.

3. The method of claim 1, wherein the first period of time is in a range of 0.3 to 4 seconds.

4. The method of claim 1, wherein the third period of time is in a range of 5 to 120 seconds.

5. The method of claim 1, wherein the metal layer includes at least one of copper or cobalt.

6. The method of claim 1, wherein the second period of time is in a range of 50 to 60 seconds.

7. The method of claim 1, wherein an ampoule temperature of an ampoule housing the MCP is in a range of 60 to 90 degrees Celsius.

8. The method of claim 1, wherein the MCP is delivered at a flow rate in a range of 50 to 2000 standard cubic centimeters per minute (sccm) for the first period of time.

9. The method of claim 1, wherein the carrier gas is delivered at a flow rate in a range of 3000 to 12000 sccm for the second period of time.

10. The method of claim 1, wherein the reactive precursor gas is delivered at a flow rate in a range of 1000 to 21000 sccm for the third period of time.

11. The method of claim 1, wherein the substrate is maintained at a pressure in a range of 5 to 50 Torr.

12. A method comprising:
forming a molybdenum nucleation layer on a metal layer disposed within a damascene structure formed in a surface of a substrate, wherein the damascene structure comprises a via and the metal layer is positioned at a bottom surface of the via, and forming the molybdenum nucleation layer comprises:
a.) delivering, during a first period of time, a molybdenum-containing precursor (MCP) to the substrate maintained at a processing temperature of less than 425 degrees Celsius;
b.) delivering, during a second period of time, a carrier gas to the substrate;
c.) delivering, during a third period of time, a reactive precursor gas to the substrate; and
d.) delivering, during a fourth period of time, the carrier gas to the substrate; and
e.) repeating a.) to d.) one or more times; and
depositing, within the via, a molybdenum layer on the molybdenum nucleation layer.

13. The method of claim 12, further comprising depositing an additional metal layer on the molybdenum layer.

14. The method of claim 12, wherein a.) to d.) are repeated 10 or more times.

15. The method of claim 12, wherein the metal layer includes at least one of copper or cobalt.

16. The method of claim 12, wherein the first period of time is in a range of 0.3 to 4 seconds.

17. The method of claim 12, wherein the third period of time is in a range of 0.3 to 4 seconds.

18. The method of claim 12, wherein the MCP is delivered at a flow rate in a range of 50 to 2000 standard cubic centimeters per minute (sccm) for the first period of time.

19. The method of claim 12, wherein the reactive precursor gas is delivered at a flow rate in a range of 1000 to 21000 sccm for the third period of time.

20. The method of claim 12, wherein the substrate is maintained at a pressure in a range of 5 to 50 Torr.
